(19) United States
(12) Patent Application Publication
(10) Pub. No.: US 2003/0076248 A1
(43) Pub. Date: Apr. 24, 2003

(54) System and method for transmitting and storing data using an enhanced encoding scheme

(76) Inventor: Mykel G. Larson, Upland, CA (US)

Correspondence Address: CISLO & THOMAS, LLP, 233 WILSHIRE BLVD, SUITE 900, SANTA MONICA, CA, 90401-1211, US

(21) Appl. No.: 10/274,239

(22) Filed: Oct. 18, 2002

Related U.S. Application Data
(60) Provisional application No. 60/350,170, filed on Oct. 24, 2001.

(51) Int. Cl. H03M 7/04; H03M 7/08

(52) U.S. Cl. 341/104

(57) ABSTRACT

A system for and method of transmitting and storing data using multidecimal encoding. A binary data stream is encoded into a multidecimal data stream. Distinct frequencies are then assigned to characters in the multidecimal data stream for transmitting the multidecimal character information. Individual frequencies, or combinations of frequencies, may be assigned to each multidecimal character to be transmitted, through various methods. The various multidecimal transmission schemes described herein may be employed in any of several transmission systems, such as fiber optics networks, analog transmission systems, DSL systems, cable modem systems, wireless communication systems, or any other suitable data transmission systems. Multidecimal data may also be stored in various storage media, such as CD-ROMs, DVDs, or RAM.

### CROSS-REFERENCE TO RELATED APPLICATIONS

This patent application is related to U.S. Provisional Patent Application Serial No. 60/350,170 filed Oct. 24, 2001 entitled SYSTEM AND METHOD FOR TRANSMITTING AND STORING DATA USING AN ENHANCED ENCODING SCHEME which application is incorporated herein by this reference thereto.

### COPYRIGHT AUTHORIZATION

A portion of the disclosure of this patent document contains material which is subject to copyright protection. The copyright owner has no objection to the facsimile reproduction by any one of the patent disclosure as it appears in the U.S. Patent and Trademark Office patent files or records, but otherwise reserves all copyright rights whatsoever.

### BACKGROUND OF THE INVENTION

1. Field of the Invention

This invention relates to data transmission methods and means and more particularly to a method and apparatus for transmitting electronic data in a more efficient manner by enabling more information to be transmitted per unit time.

2. Description of the Related Art

Data transmission is a fundamental function of computer systems, cable systems, wireless communication systems, etc. These systems generally transmit data on a low level, namely, the bit level, via a binary encoding scheme. Binary encoding involves assigning a string of “ones” and “zeros” to a stream of data, wherein each “one” and each “zero” represents a bit of data. For example, the following binary data stream would be used to encode, using standard ASCII codes, the phrase “A fish called Wanda”:

100000100100000011001100110100111100110110100000100000

110001111000010110110001101100011001011100100001000000

10101110110000111011100110010001100001

As can be seen, a relatively long binary data stream is required to characterize a relatively short phrase in the English language. It follows that extremely long binary data streams are required to characterize considerably larger amounts of data. These binary data streams are generally transmitted one character at a time and read in “packets” of eight bits (eight ones and zeros). The ones and zeros are transmitted over two transmission frequencies, one “baseline” frequency for indicating that a binary character is in fact being transmitted, and one frequency representing a one or a zero corresponding to a character in the binary data stream. As the size of a binary data stream increases, the number of packets that must be transmitted increases, and the overall amount of time required to transmit the data increases accordingly. As a result, a relatively significant amount of time is required to transmit a long binary data stream representing a large amount of data.

Additionally, in any data packet-based network where routing paths are dynamic, such as a TCP/IP network, there is always the possibility that data packet traffic will collect in a particular “gateway.” As the amount of traffic that is routed toward a particular gateway increases (generally due to the relatively significant lengths of binary data streams), the probability for packet loss also increases, because a gateway can handle only a limited amount of traffic over a given time interval. Software and hardware buffers provide a temporary alleviation to these “traffic jams,” but buffers have limits, and packet loss still occurs.

Nevertheless, existing infrastructure, regardless of the transport mechanisms employed, use binary encoding schemes to transmit and receive data. While this present encoding scheme is functional on many levels, as the demand for an increase in transmission and processor speeds has grown, the problem has arisen as to how to increase signaling speeds when transmitting data.

Speed is generally a measure of how far something travels per unit time. As a result, when attempting to make something travel faster, most innovators look for ways to accelerate or increase the velocity at which it travels. With regard to binary data transmission, speed increases are generally accomplished by increasing the speed at which single distinct frequency pulses of light, sound, and electricity can be transmitted and read. There are inherent limits, however, to how “fast” these frequency pulses can be transmitted. As an illustration, imagine a piano having a white key representing a one, and a black key representing a zero. Then, envision how many times one would be able to play those two keys within one second. The number of times is quite limited, as is the number of binary data bits that can be transmitted over a given time period. While data compression methods have been developed that eliminate redundancy in data representations to reduce memory requirements and/or the load on input-output channels in various transmission systems, the amount of data that can be transmitted over a given time interval is still limited by the binary nature of the data streams.

### SUMMARY OF THE INVENTION

In view of the foregoing disadvantages inherent in the known types of data-transmission methods now present in the prior art, the present invention provides a new system of data transmission wherein more data can be transmitted per unit time in order to increase data speeds.

The general purpose of the present invention, which will be described subsequently in greater detail, is to provide a better system of data transmission which is not anticipated, rendered obvious, suggested, taught, or even implied by any of the prior art data-transmission methods, either alone or in any combination thereof.

The present invention is directed to a system for and a method of transmitting and storing data using an enhanced multidecimal encoding system, preferably a hexadecimal encoding system. By using multidecimal encoding, more data may be transmitted within the same time segments used by current signaling hardware without physically increasing the signaling speed of the hardware itself.

According to a first aspect of the invention, a binary data stream is encoded into a hexadecimal data stream comprising hexadecimal character pairs, or hex-bytes, which are represented by a combination of 16 possible characters ranging from 0 to F (0=0, F=15). Each of the 16 characters is assigned with a distinct frequency, or a combination of frequencies, over which the character information may be transmitted. The hexadecimal pairs are then split apart into single characters, and frequency pulses corresponding to the individual hexadecimal characters are transmitted to a receiver.

According to another aspect of the invention, a distinct frequency, or a combination of frequencies, is assigned to each of 256 possible hexadecimal character pairs, such that no splitting of the character pairs is required. The frequency pulses corresponding to the hexadecimal character pairs are then transmitted to a receiver.

According to another aspect of the invention, a frequency, or a combination of frequencies, from a first set of transmission frequencies is assigned to a first half-byte of a hexadecimal character pair. Then, if the first half-byte is determined not to be equal to the second half-byte of the hexadecimal character pair, a frequency, or a combination of frequencies, from the same set of data transmission frequencies is assigned to the second half-byte. If, conversely, the first half-byte is equal to the second half-byte, a frequency, or a combination of frequencies, from a second set of data transmission frequencies is assigned to the second half-byte. Frequency pulses corresponding to the frequencies assigned to the two half-bytes are then transmitted simultaneously, thereby forming a unique signal corresponding to a hexadecimal value. Alternatively, a frequency, or a combination of frequencies, from the second set of data transmission frequencies may be assigned to the second half-byte regardless of whether the first and second half-bytes are equal to one another.

In another aspect of the invention, a selection of fiber strands in a fiber cable, each representing a distinct integer value, is activated such that distinct frequency pulses corresponding to the activated integer values are transmitted. The sum of the activated integer values represents the hexadecimal character value to be transmitted.

### OBJECTS OF THE INVENTION

It is an object of the present invention to provide faster data transmission.

It is another object of the present invention to enable and achieve data compression for faster data transmission.

It is yet another object of the present invention to enable and achieve the parallel transmission of data by the simultaneous use of a plurality of data lines.

These and other objects and advantages of the present invention will be apparent from a review of the following specification and accompanying drawings.

### BRIEF DESCRIPTION OF THE DRAWINGS

FIG. 1 is a diagrammatic view of an analog frequency transmission system for transmitting hexadecimal data.

FIG. 2A is a chart illustrating a hexadecimal encoding scheme for transmitting 16 different hexadecimal characters.

FIG. 2B is a chart illustrating an alternative hexadecimal encoding scheme for transmitting 16 different hexadecimal characters.

FIG. 2C is a chart illustrating another alternative hexadecimal encoding scheme for transmitting 16 different hexadecimal characters.

FIG. 3 is a flow diagram illustrating a process of encoding and transmitting a hexadecimal stream according to a preferred embodiment.

FIG. 4 is a cross-sectional view of a fiber cable having eight transmission fiber strands corresponding to eight distinct hexadecimal integer values.

FIG. 5A is a cross-sectional view of the fiber cable of FIG. 4 showing a first hexadecimal value being transmitted.

FIG. 5B is a cross-sectional view of the fiber cable of FIG. 4 showing a second hexadecimal value being transmitted.

FIG. 5C is a cross-sectional view of the fiber cable of FIG. 4 showing a third hexadecimal value being transmitted.

FIG. 6 is a cross-sectional view of a fiber cable having a hexadecimal data transmission node and a hexadecimal data reception node.

FIG. 7A is a cross-sectional view of a fiber matrix having 256 hexadecimal data transmission nodes.

FIG. 7B is a cross-sectional view of a hexadecimal data transmission node of FIG. 7A.

FIG. 8 is a fiber matrix communication system having a plurality of fiber matrices in communication with a central fiber core.

FIG. 9 is a cross-sectional view of a fiber cable having two transmission fiber strands and two reception fiber strands.

FIG. 10 is a diagrammatic view of a fiber optic signal transmission system for transmitting hexadecimal data.

### DESCRIPTION OF THE PREFERRED EMBODIMENT(S)

The detailed description set forth below in connection with the appended drawings is intended as a description of presently-preferred embodiments of the invention and is not intended to represent the only forms in which the present invention may be constructed and/or utilized. The description sets forth the functions and the sequence of steps for constructing and operating the invention in connection with the illustrated embodiments. However, it is to be understood that the same or equivalent functions and sequences may be accomplished by different embodiments that are also intended to be encompassed within the spirit and scope of the invention.

The preferred embodiments will now be described with reference to the drawings. To facilitate description, element numerals designating an element in one figure will represent the same element in any other figure. The various methods and systems described herein relate to transmitting and storing data encoded in a hexadecimal format, to allow for quicker packet transmission and retransmission of lost data packets in packet-based networks, as further described below. The various methods may be applied, however, to any formal system of representing data structures that require more than two discreet values for assembly (hereinafter referred to as “multidecimal” systems). A hexadecimal encoding scheme is preferred simply because the translation from binary to hexadecimal data streams is less complex and requires less character and data manipulation than translations to other encoding schemes.

Instead of comprising bits represented by ones and zeros, as in a binary data stream, hexadecimal data streams comprise up to 256 distinct codes, ranging from 00 to FF. Each of these 256 hexadecimal codes has an integer value associated therewith, ranging from 0 to 255 (00=0, FF=255), and each hexadecimal code element represents one byte of binary data. A “byte,” or element, of hexadecimal data is made up of two characters, or two “half-bytes,” and each byte of hexadecimal data represents eight bits of binary data. In other words, a hexadecimal byte contains eight times more data than that contained in a binary bit.

The present inventor has recognized that hexadecimal encoding may also be used when transmitting data, such that eight times or more data may be transmitted over a given time interval, at a given signaling speed, than that which is transmitted using binary encoding. In a preferred transmission system, distinct frequencies, or combinations of frequencies, are assigned to distinct hexadecimal characters in a hexadecimal data stream, and pulses corresponding to the assigned frequencies (hereinafter referred to as “frequency pulses”) are transmitted, either consecutively or simultaneously, to represent the hexadecimal data, as further described below.

While more data may be transmitted over a given time interval using hexadecimal encoding, a greater amount of bandwidth, comprising a plurality of transmission frequencies, is required to transmit hexadecimal data than that which is used to transmit a binary data stream, which requires only two transmission frequencies. In some applications, maximizing the amount of available bandwidth is desired. Accordingly, when using hexadecimal encoding to transmit data, it is often preferable to maximize the amount of data transmitted, while minimizing the amount of bandwidth that is required to transmit frequency pulses representing the hexadecimal data.

The data transmission systems and methods disclosed herein may be implemented into several existing systems, or into new systems, through various methods. The disclosed transmission systems may be used in analog transmission systems, fiber optic communication systems, wireless communication systems, digital subscriber line (DSL) communication systems, cable modem transmission systems, or any other systems suitable for data transmission. Various preferred data transmission systems and methods are described below.

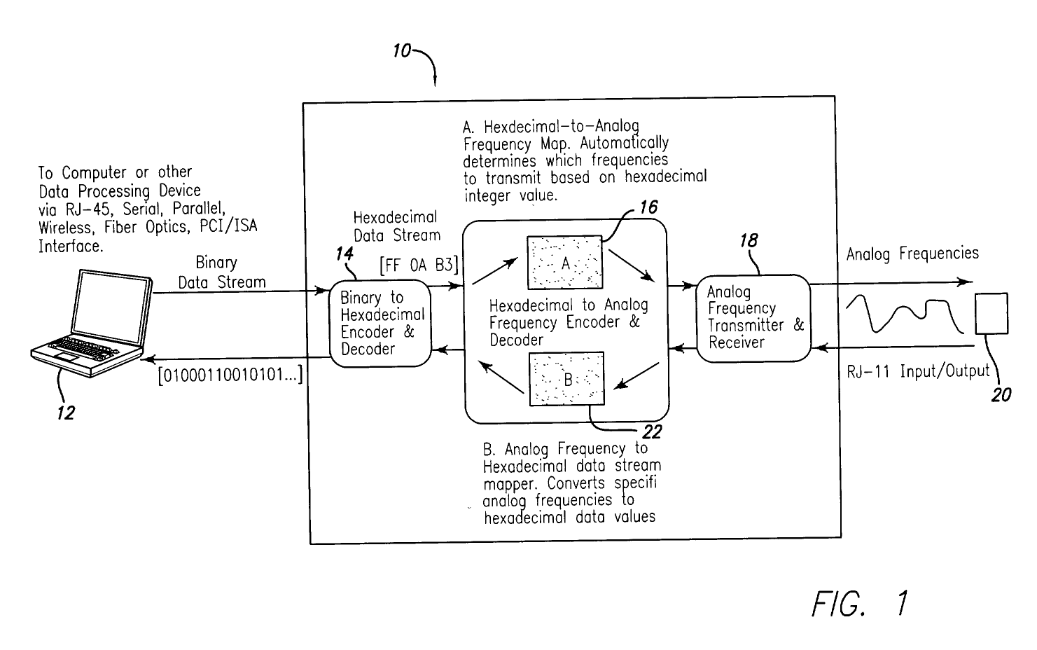

FIG. 1 is a diagrammatic illustration of an analog frequency transmission system 10 in which a binary data stream is encoded into a hexadecimal data stream, and transmitted as such, using, in this example, an analog frequency splitting and signaling process. Specific hexadecimal data transmission methods utilizing analog frequencies will be described in greater detail below.

Still referring to FIG. 1, in operation, a computer 12, or other suitable data processing device, sends a binary data stream to a binary-to-hexadecimal data encoder/decoder 14, which converts the binary ones and zeros into a stream of hexadecimal character pairs. In a preferred configuration, 16 distinct characters, ranging from 0 to F (i.e., 0 to 9, and A-F), are used to construct the character pairs. As a result, 256 distinct hexadecimal values ranging from 0 to 255 (00=0, FF=255), represented by the 256 possible combinations of character pairs, are encoded by the hexadecimal data encoder/decoder 14. The hexadecimal data stream is then sent to a hexadecimal-to-analog frequency encoder 16, which assigns distinct analog frequencies to the individual character pairs, or to the individual characters themselves, as further described below.

In current analog transmission systems, four specific frequencies, two for transmitting ones and zeros, and two for reading ones and zeros, are used for transmitting and receiving binary data. Separate frequencies are employed to ensure that the transmission frequencies and the reception frequencies do not overlap, or “bleed,” which could cause bit and data errors. The specific frequencies employed generally range between 400 and 3400 Hz, because analog equipment generally filters out any frequencies transmitted below or above that range. Thus, the analog frequencies selected for the hexadecimal characters preferably fall within the range of 400 to 3400 Hz.

After the hexadecimal-to-analog frequency encoder 16 assigns frequencies to the characters/character pairs in the hexadecimal data stream, an analog frequency transmitter/receiver 18 transmits frequency pulses corresponding to the assigned frequencies out through an input/output device 20 to a desired destination(s) along a transmission medium, such as an analog phone line.

When analog frequency pulses corresponding to hexadecimal characters are sent into the system 10 from an outside source, the incoming frequency pulses are received through the input/output device 20 and sent to the analog frequency transmitter/receiver 18. The analog frequency transmitter/receiver 18 receives the analog frequency pulses and sends them to an analog-to-hexadecimal data decoder 22, which converts the analog frequency pulses into a hexadecimal data stream. The hexadecimal data stream is then sent to the binary-to-hexadecimal data encoder/decoder 14, which converts the hexadecimal data stream into a binary data stream, which is then sent to the computer 12 for processing. Accordingly, the analog frequency transmission system 10 is able to transmit and receive data encoded in a hexadecimal format.

Several different methods may be used to implement a hexadecimal encoding scheme into an analog frequency transmission system, such as that illustrated in FIG. 1. The first method is referred to as frequency splitting, wherein a specific range of frequencies is split into a distinct number of frequencies for transmitting a hexadecimal integer value. This method involves converting or encoding a binary data stream into a hexadecimal data stream, comprising a series of hexadecimal character pairs. Each hexadecimal character pair includes two characters selected from a group of 16 possible characters ranging from 0 to F (i.e., 0-9, and A-F), which represent 16 hexadecimal integer values ranging from 0 to 15 (0=0, F=15). For example, if the following 128 bit binary data stream:

01100001000000100001111100000100100001000000001011101101

00000011100001000000001011100100000000111000010000000010

1110000100000011

were encoded, using conventional encoding techniques, into a hexadecimal data stream, it would yield the following 16 hexadecimal character pairs:

61 02 1F 04 84 02 ED 03 84 02 E4 03 84 02 E1 03. (2)

Each of these hexadecimal character pairs represents one hexadecimal byte, or hex-byte, of data. The hex-bytes are then split into 32 individual characters, or half-bytes, thus producing the following data stream:

6 1 0 2 1 F 0 4 8 4 0 2 E D 0 3 8 4 0 2 E 4 0 3 8 4 0 2 E 1 0 3. (3)

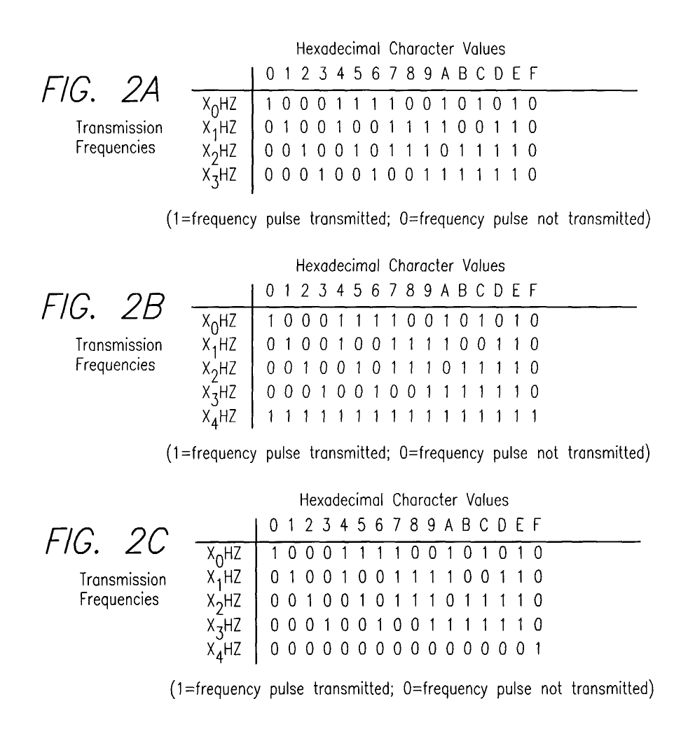

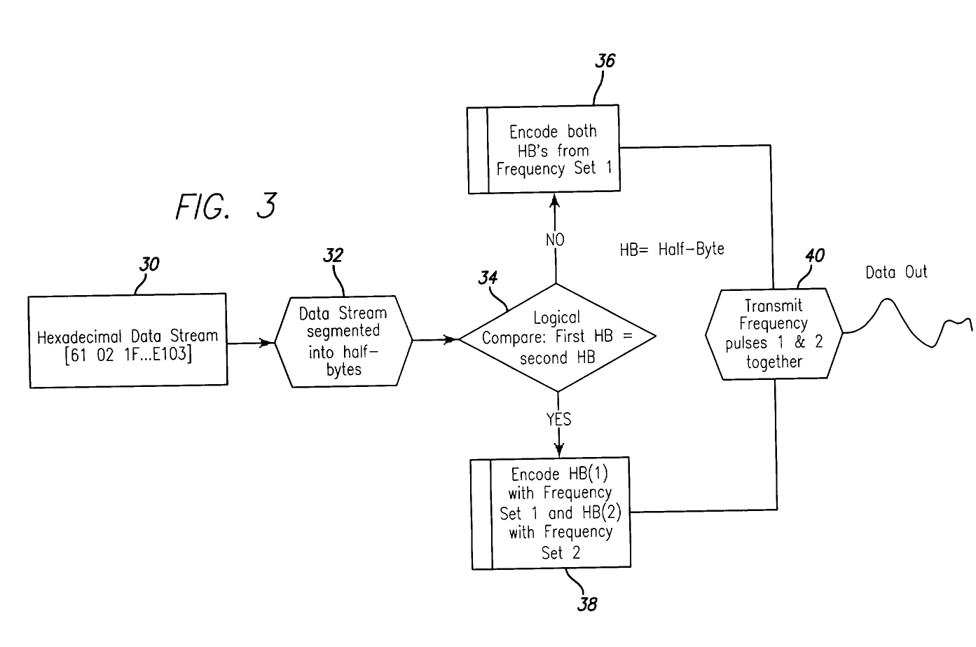

In a preferred embodiment, four transmission frequencies, X0 Hz, X1 Hz, X2 Hz, and X3 Hz, selected from a frequency range of approximately 400 and 3400 Hz, are chosen for transmitting each of the 16 hexadecimal characters 0-F. Alternatively, a greater number of frequencies could be used to transmit a greater number of hexadecimal characters, such as the 256 hexadecimal characters 00 to FF. Each hexadecimal character is represented by a specific combination of the selected frequencies, as shown by the “ones” in the table of FIG. 2A. A hexadecimal character is sent to a destination by simultaneously transmitting a combination of frequency pulses corresponding to the frequencies where a “one” is indicated for that character. For example, to transmit the hexadecimal character “8”, pulses at X1 Hz and X2 Hz are simultaneously transmitted along a suitable transmission medium, such as an analog phone line or fiber optic cable. The particular combinations of ones and zeros corresponding to the specified hexadecimal characters shown in the table of FIG. 2A are shown by way of example only, and any of the combinations of ones and zeros may be assigned to any of the hexadecimal characters.

By transmitting a hexadecimal character using four transmission frequencies, four times more data is transmitted, over a given time interval, than that which is transmitted using a binary transmission system (one hexadecimal character or half-byte represents four binary bits). Additionally, because only four transmission frequencies are required to transmit any one of the 16 hexadecimal characters, the bandwidth required is only twice that used in a binary transmission system (a binary transmission system uses two transmission frequencies to consecutively transmit ones and zeros, as described above). Accordingly, a significantly larger amount of data is transmitted over a given time interval, with a relatively minimal loss of available bandwidth, due to the greater volume of data that is transmitted over a limited number of frequencies.

In a method utilizing only four transmission frequencies, a predetermined set time interval is preferably employed between the transmission of consecutive hexadecimal characters, such that the system is able to accommodate the transmission of all sixteen hexadecimal characters, 0-F. The set time interval allows for the “transmission” of a character that is represented by four “zeros” (i.e., where none of the four frequencies are transmitted), such as “F” in the table of FIG. 2A. In other words, by utilizing a set time interval, the system “knows” when a character is being sent, and it is therefore able to recognize a character when no pulses are transmitted. For example, if the set time interval is 1 ms, and the values “6”, “B”, “F”, and “2” from the table in FIG. 2A are to be sent consecutively, the following occurs:

in the first time interval #1, frequency pulses at X0 Hz and X3 Hz are sent simultaneously to represent the character “6”;

in the next time interval #2, one millisecond later, frequency pulses at X2 Hz and X3 Hz are sent simultaneously to represent the character “B”;

in the next time interval #3, one millisecond later, no pulses are sent, to represent the character “F”; and

in the next time interval #4, one millisecond later, a frequency pulse at X2 Hz is sent to represent the character “2”.

If this set interval method is utilized, a signal or other suitable indicator is preferably used to signify both the beginning and the end of the transmission of a data stream, such that the system is able to recognize situations where a hexadecimal character represented by four “zeros” is the first and/or last character transmitted in a data stream. The signal could be electronic, or could be a physical action within the system that indicates the beginning and/or the end of a data stream transmission.

As an alternative to the set time interval method, a pulse at a fifth transmission frequency may be sent simultaneously with the transmission of each hexadecimal character in a data stream, in order to indicate that a character is in fact being transmitted. For example, referring to the character values in the table of FIG. 2B, a frequency pulse at X4 Hz may be transmitted simultaneously with pulses at X2 Hz and X3 Hz to indicate that the character “B” is being sent, and a frequency pulse at X4 Hz may be transmitted alone to indicate that the character “F” is being sent. Alternatively, a pulse at the fifth transmission frequency may be sent only to represent the value “F”, as illustrated by the encoding scheme embodied in the table of FIG. 2C. In this embodiment, the fifth transmission frequency is not used when transmitting any of the other 15 hexadecimal characters. While these two methods each require a fifth transmission frequency to transmit the 16 hexadecimal characters, and therefore require slightly more bandwidth to accommodate the expanded frequency range, both methods eliminate the need to employ and recognize a set time interval between character transmissions.

In another embodiment, each of the 16 hexadecimal characters, 0 to F, is assigned a distinct analog frequency from the range of available frequencies, preferably from 400 to 3400 Hz. Each of the hexadecimal characters in a given data stream is thus assigned a distinct analog frequency. This embodiment is preferably used in a data transmission application wherein minimizing the amount of bandwidth used is not a controlling factor, since 16 separate transmission frequencies are used. After the distinct frequencies are assigned to the hexadecimal characters in a data stream, a series of pulses are transmitted at the assigned frequencies to a desired destination(s), such as a suitable data receiver. Thus, to transmit the entire data string (3) from the above example, 32 consecutive pulses are transmitted, as opposed to the 128 pulses that would have to be transmitted if a binary transmission system were used. Accordingly, this frequency splitting method results in data being transmitted four times faster (128/32=4) than it would have been transmitted using a binary transmission method, without increasing the actual signaling speed of the hardware itself.

Alternatively, 256 distinct analog frequencies, X0 Hz, X1 Hz . . . X255 Hz, may be assigned to 256 distinct hexadecimal integer values ranging from 0 to 255. Each of the 256 integer values is represented by a hexadecimal character pair selected from a group of character pairs ranging from 00 to FF (00=0, FF=255). In this embodiment, a binary data stream is converted into a stream of hexadecimal character pairs, such as the stream of 16 character pairs from data string (2) above.

Each character pair is then encoded with its assigned frequency, and pulses at the distinct frequencies are transmitted consecutively to a desired destination(s), such as a suitable data receiver. As a result, to transmit this data string, only 16 consecutive frequency pulses are transmitted, as opposed to the 128 pulses that would have to be transmitted if a binary transmission system were used. Accordingly, this frequency splitting method results in data being transmitted eight times faster (128/16=8) than it would have been transmitted using a binary transmission method, without increasing the actual signaling speed of the hardware itself.

To further increase data transmission efficiency, 256 distinct time intervals may be assigned to the hexadecimal integer values from 0 to 255. These distinct time intervals may then be used to separate frequency pulses during transmission, in order to represent additional hexadecimal values. For example, if the time intervals of 1 ms and 1.1 ms are assigned to the hexadecimal integer values of “247” and “43”, respectively, and the data stream “24 247 124 43 89” is to be transmitted, the assigned frequency pulses corresponding to “24” and “124” are transmitted 1 ms apart, and the assigned frequency pulses corresponding to “124” and “89” are transmitted 1.1 ms apart, to represent the desired hexadecimal data stream. In other words, the time intervals of 1 ms and 1.1 ms represent the hexadecimal integer values of “247” and “43”, respectively. Thus, each hexadecimal integer value may be assigned a distinct time interval, and the distinct time intervals may separate frequency pulses during data transmission to represent hexadecimal integer values.

FIG. 3 is a flow diagram illustrating another preferred method of transmitting data using hexadecimal encoding. The method utilizes frequency splitting and combinatorics to transmit data at a rate eight times faster than that achieved by transmitting the same data using a binary transmission method. In this method, two separate sets of transmission frequencies are provided, each preferably containing 16 distinct frequencies assigned to 16 distinct hexadecimal integer values ranging from 0 to 15.

In operation, a hexadecimal data stream 30 comprising hexadecimal character pairs, or bytes, is segmented into individual characters, or half-bytes, as shown at step 32. The half-bytes comprise values ranging from 0 to F, which correspond to the hexadecimal integer values 0 to 15 (0=0, F=15). The first half-byte of a segmented character pair is encoded with its corresponding frequency from the first set of data transmission frequencies. The second half-byte is then compared to the first half-byte, as shown at step 34, to determine whether the two half-bytes represent the same integer value. If they do not represent the same integer value, the second half-byte is encoded with its corresponding frequency from the first set of transmission frequencies, as shown at step 36.

If, on the other hand, the two half-bytes do represent the same integer value, the second half-byte is encoded using its corresponding frequency from the second set of transmission frequencies, as shown at step 38. Once the two frequencies are selected, frequency pulses at those frequencies are transmitted simultaneously, as shown at step 40, thereby creating a unique analog transmission signal. Because the two frequency pulses, which together correspond to a hexadecimal character pair, are transmitted simultaneously, the same amount of data is transmitted over a given time interval as is transmitted in the frequency splitting method that uses 256 distinct frequencies to transmit data. Accordingly, data is transmitted eight times faster than it would have been transmitted using a binary transmission method, without increasing the actual signaling speed of the hardware itself. Because the second set of transmission frequencies is only used when the two half-bytes represent the same integer value, a means for interleaving the use of the bandwidth associated with those frequencies is preferably employed so that the bandwidth is only used when necessary.

Alternatively, in a system where minimizing the bandwidth occupied is not a controlling factor, the second half-byte may be encoded with a corresponding frequency from the second set of transmission frequencies regardless of whether or not the two half-bytes represent the same integer value. Pulses at each of the two selected frequencies are then transmitted simultaneously, thus realizing an eight-time speed increase over a binary transmission system, without increasing the signaling speed of the hardware itself.

Another method of utilizing frequency splitting and combinatorics entails providing a plurality of distinct frequencies in which to create “chord” signals. A method utilizing eight distinct frequencies will be described by way of example only. Methods utilizing a greater or lesser number of frequencies may also be used.

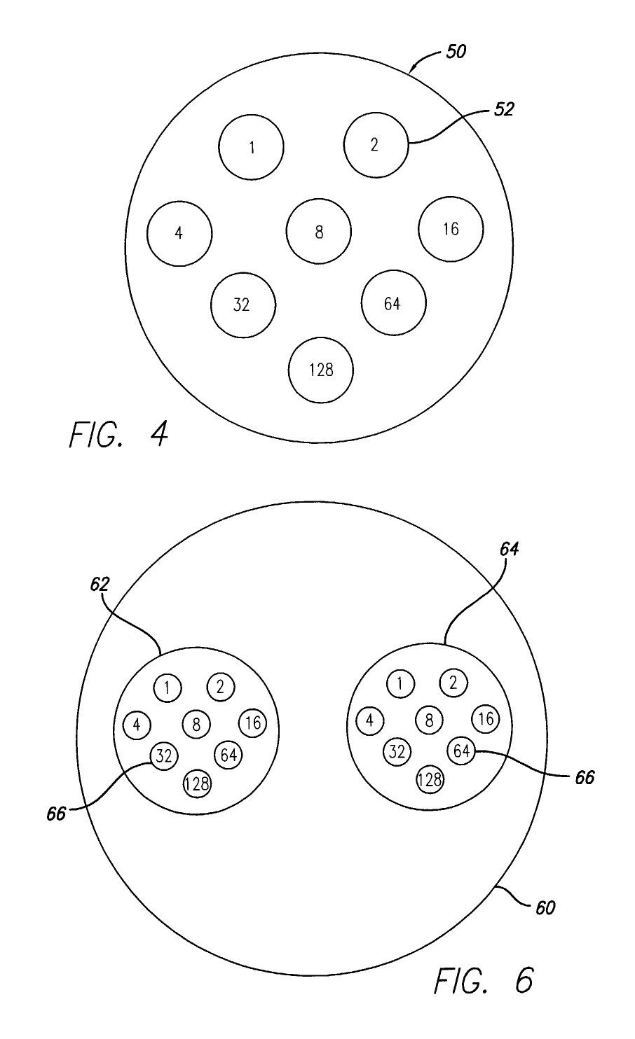

The eight frequencies correspond to eight distinct binary integer values, each of which may be turned “on” or “off.” In this embodiment, the eight binary integer values are 1, 2, 4, 8, 16, 32, 64, and 128, but they may vary depending on the desired configuration. The binary integer values are embodied in a suitable transmission medium, such as fiber strands 52 in a fiber optic cable 50, as shown in FIG. 4. When a combination of integer values are “turned on,” or activated, their values are transmitted simultaneously along the medium in which they are embodied, such that a hexadecimal character value represented by the sum of their values is transmitted. For example, if the binary integer values of “1”, “8”, and “128” are activated, the hexadecimal value of “137” (1+8+128=137) is transmitted along the transmission medium. Accordingly, by turning various binary integer values on or off, any hexadecimal value ranging from 0 to 255 may be transmitted (0 when all eight integer values are deactivated; 255 when all eight integer values are activated).

The distinct frequencies are preferably selected such that they are spaced apart from one another within the range of available frequencies, particularly in the case of analog transmission systems, in order to prevent frequency bleeding. Frequency bleeding may occur when two frequency pulses, which are too close to one another within a given frequency range, are transmitted simultaneously, thus causing unclear transmission of the frequency pulses.

As mentioned above, the binary integer values may be encased in a fiber cable 50, as shown in FIG. 4, such as that used in a fiber optics communication network. The binary integer values are preferably embodied in eight fiber strands 52 within the fiber cable 50. Several such fiber cables are preferably linked to one another to establish a fiber optics communication network. The binary integer values are preferably turned on and off by an optical signal transmitter such as a laser, or by any other suitable activation means, to simultaneously transmit the hexadecimal data.

A fiber optics network generally does not rely on frequency splitting to transmit hexadecimal data streams. Thus, there is no need to split frequencies into several small transmission channels. Instead, throughout the fiber optics network, optical signals, such as pulses of light, are transmitted to represent the hexadecimal data. Additionally, the optical signals may be sent to and from the central processing unit (CPU) of a computer system, to facilitate communication between the computer system and various other processing systems.

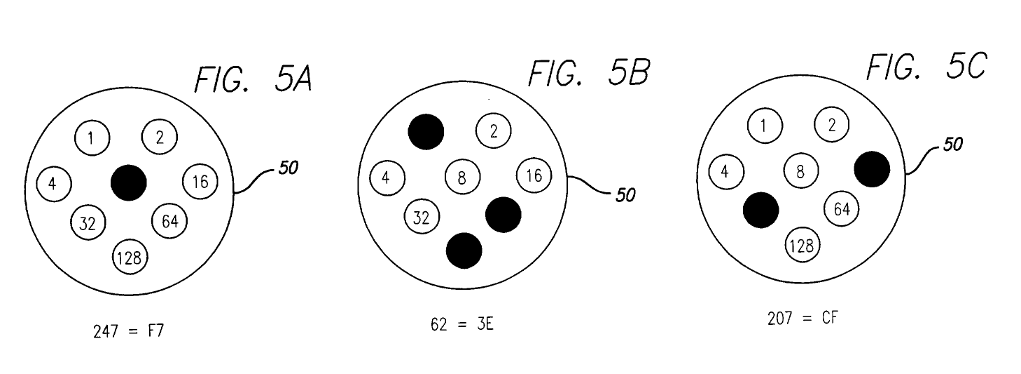

FIGS. 5A-5C illustrate three embodiments of the fiber cable 50 wherein various binary integer values are turned on and off to represent the hexadecimal values “247”, “62”, and “207”, respectively. Turning to FIG. 5A for illustration, only the binary placeholder representing the integer value of “eight” is turned off, as shown by the blackened fiber strand. When the activated integer values are added together, their sum equals “247.” Thus, in FIG. 5A, distinct optical signals representing the hexadecimal value of “247” are simultaneously transmitted via the fiber cable 50. In a similar manner, the activated integer values illustrated in FIGS. 5B and 5C are added together to yield the hexadecimal values of “62” and “207,” respectively. Accordingly, optical signals representing the hexadecimal values of “62” and “207” are transmitted in the embodiments illustrated in FIGS. 5B and 5C, respectively.

FIG. 6 is a cross-sectional view of a fiber cable 60 having a transmission node 62 and a reception node 64. Each node includes eight binary integer values embodied in eight fiber strands 66, preferably representing the values 1, 2, 4, 8, 16, 32, 64, and 128. Hexadecimal values are transmitted along the transmission node 62, and received along the reception node 64, in a manner similar to that described above. Accordingly, any hexadecimal value ranging from 0 to 255 may be transmitted and received along the fiber cable 60. Several such fiber cables may be linked together to establish a fiber optics communications network for transmitting and receiving hexadecimal data to and from various communications systems, such as computer processors, telephone systems, or any other transmission systems suitable for use in a fiber optics communication network.

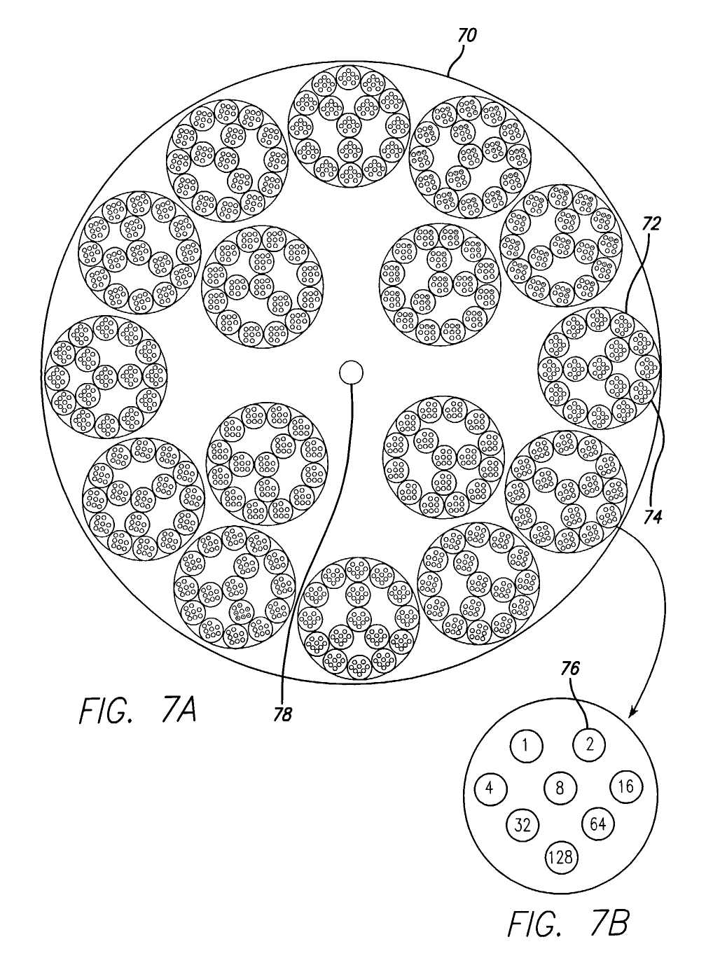

FIG. 7A is a cross-sectional view of a fiber matrix 70 that may be implemented into a network and/or computer system architecture for transmitting massive amounts of data at very high speeds. The fiber matrix 70 preferably includes 16 fiber node matrices 72, each comprising 16 hexadecimal data transmission and/or reception nodes 74. Thus, the fiber matrix 70 includes 256 data transmission/reception nodes altogether. Each data transmission/reception node 74 preferably includes eight fiber strands 76, as shown in FIG. 6B. The eight binary integer values 1, 2, 4, 8, 16, 32, 64, and 128 are preferably embodied in the fiber strands 76, as shown in FIG. 7B. Thus, hexadecimal data may be simultaneously transmitted/received along 256 separate nodes, such that massive amounts of hexadecimal data are communicated over a given time period. The fiber matrix 70 preferably further includes a singular fiber node 78 for transmitting and receiving system commands and instructions to and from other fiber matrices, as described below.

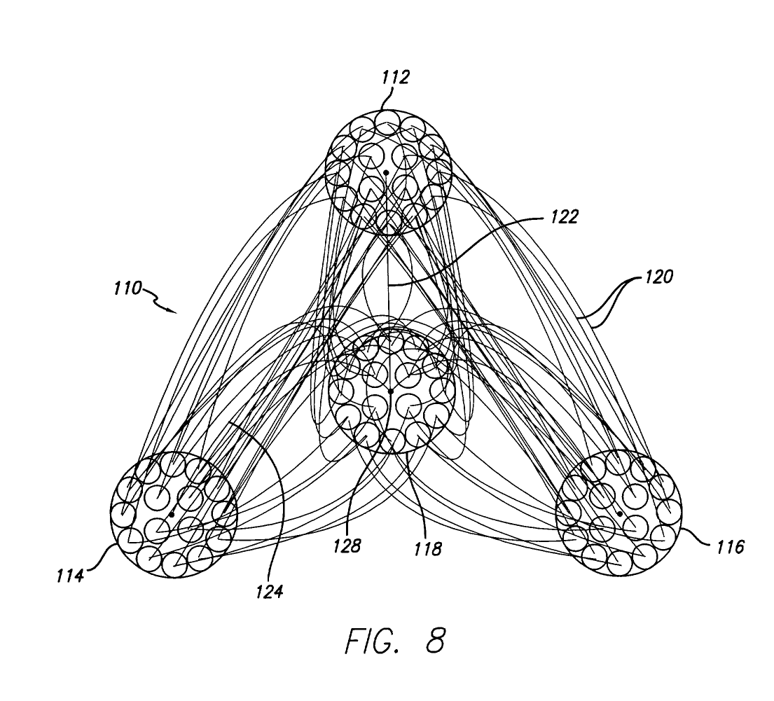

FIG. 8 illustrates a fiber matrix communication system 110 having a plurality of fiber matrices, 112, 114, 116 in communication with one another, and with a central fiber core 118, via a plurality of fiber optic cables 120. The number of fiber matrices employed may vary based on system requirements, and three matrices 112, 114, 116 are shown by way of example only. Each of the fiber matrices 112, 114, 116 may be embodied in a hard drive interface, a mass storage device, a high speed network connection, a RAM interface, or any other suitable data transmission/storage component within a network or computer system.

A singular fiber node at the center of each of the fiber matrices 112, 114, 116 is connected to a central node 128 of the central fiber core 118 via central fiber cables 122, 124, 126, respectively. The central fiber core 118 transmits system commands and operating instructions, independent of the hexadecimal data transmitted throughout the system 110, to the fiber matrices 112, 114, 116 along the central fiber cables 122, 124, 126. In this manner, the central fiber core 118 acts as a system director that creates light frequency pathways for routing packets of hexadecimal data to the proper system destinations. In a preferred embodiment, the central fiber core 118 creates the light frequency pathways via a switch mechanism that operates like a gate. When the switch is in the “down” position, data may be transmitted across the switch. When the switch is in the “up” position, a gap is formed over which data may not be transmitted. The switch may move up and down via an electrically powered mechanism, or via any other suitable means.

By using the central fiber core 118 as an optical routing mechanism, the speed at which a system processor may operate is greatly increased because the processor does not have to route data through itself to manage the data. Instead, the hexadecimal data is transmitted and received between the fiber matrices 112, 114, 116, according to routing instructions provided by the central fiber core 118, without the data being sent through the system processor.

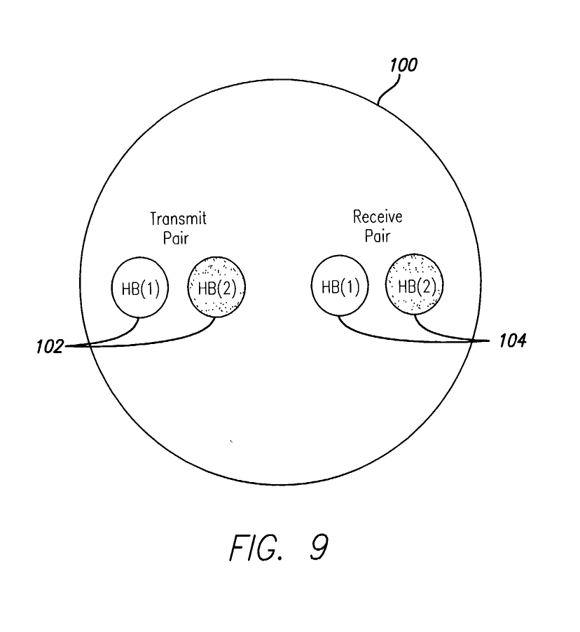

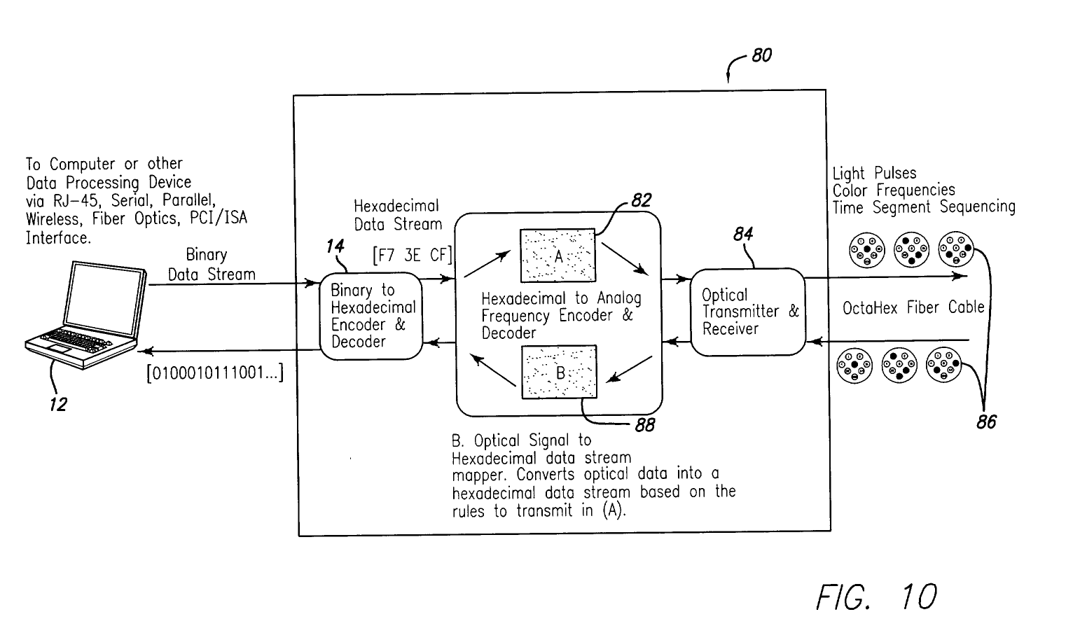

Turning to FIG. 9, a hexadecimal data transmission scheme may also be implemented into an existing fiber optic cable 100, which includes a transmission pair 102 and a reception pair 104 of fiber strands, as opposed to having nodes with eight separate fiber strands. The fiber pairs in current systems are used to signal “on” and “off” for the binary values of 1 and 0. These pairs may instead be used to transmit a hexadecimal data stream by splitting individual bytes of the hexadecimal data stream into half bytes and transmitting them together along a fiber pair, in a manner similar to that used in the frequency splitting analog systems described above.

When a hexadecimal data transmission scheme is implemented into an existing fiber optic cable network, 16 colors of “light,” or light frequencies, are preferably used to transmit the hexadecimal data. The strands in a fiber optic cable are shielded from one another and do not “bleed” into each other as sound does in an analog system. Accordingly, the same set of 16 light frequencies may be assigned to 16 half-byte characters from 0 through F (0-15, as described above), without the concern of frequency bleeding occurring. After two half-bytes of a hex-byte are each assigned a light frequency, light pulses at the assigned frequencies are transmitted simultaneously along the transmission pair 102 of fiber strands, thus creating a unique optical signal corresponding to an entire byte of hexadecimal data. In a similar manner, two light frequencies corresponding to two half-bytes of hexadecimal data may be received simultaneously along the receiving pair 104 of fiber strands.

In another embodiment, a fiber optic cable may include any number of fiber strands for transmitting and/or receiving hexadecimal data via light frequency pulses corresponding to 256 distinct hexadecimal values (ranging from 0 to 255, as described above). In such an embodiment, a distinct light frequency, or “color,” is assigned to each of the 256 distinct hexadecimal character pairs 00 to FF. Light frequency pulses corresponding to the hexadecimal character pairs in a hexadecimal data stream may then be transmitted along the fiber strands. Multiple light frequency pulses may be transmitted simultaneously along multiple fiber strands. Accordingly, the amount of data that may be transmitted over a given time interval is a function of the number of fiber strands employed in the fiber cable.

FIG. 10 is a diagrammatic view of a fiber optic signal transmission system 80 for transmitting hexadecimal data. Many of the system components are the same as, or similar to, those illustrated in FIG. 1. Several other components relating to optical signal transmission, however, replace the analog frequency transmission components of FIG. 1. The hexadecimal-to-analog frequency encoder 16 is replaced with a hexadecimal-to-optical data encoder 82, which assigns optical data to the hexadecimal data received from the binary-to-hexadecimal data encoder/decoder 14. Additionally, the analog frequency transmitter/receiver 18 is replaced with an optical data transmitter/receiver 84, which sends and receives optical signals to and from a fiber optic cable network 86. Furthermore, the analog-to-hexadecimal data decoder 22 is replaced with an optical data-to-hexadecimal data decoder 88, which converts the optical signals received from the optical data transmitter/receiver 84 into hexadecimal data values.

In addition to the data transmission components described herein, any of the above systems may further include data storage devices for storing hexadecimal data. Data storage devices essentially perform the functions of reading and writing data. Several existing data storage mediums may be modified to accommodate hexadecimal data storage.

One possible data storage method involves storing the hexadecimal data in a computer system's Random Access Memory (RAM). RAM serves as a means to temporarily store data inside a computer system. In order to make computer systems work faster, via transporting hexadecimal data streams, the RAM must both store data and transport the data throughout the system.

Current RAM stores data in binary format, using ones and zeros. When a binary data stream is transmitted, gates within the computer system open and close sequentially in order to send the binary data stream to the system processor. Hexadecimal-based RAM may be implemented in a similar fashion, wherein hex-bytes are transmitted sequentially in order to send a hexadecimal data stream to the system processor. One manner in which this may be achieved is by using an eight-strand fiber matrix, as described above, to signal hexadecimal information to and from the system processor.

Implanting hexadecimal-based RAM into a computer system requires no physical increase in system transmission speed. The various current forms of RAM are transmitted eight to 20 times slower than the actual clock speed at which the system processor operates. Thus, the physical design of hexadecimal-based RAM may be implemented into current hardware designs that use binary RAM, and hexadecimal data streams may then be sequenced and transmitted.

Another hexadecimal data storage method involves storing the data on CD-ROMs and/or DVDs. Current CD-ROMs and DVDs store data via microscopic bumps that are “burned” onto the disc surfaces. The presence of a bump represents a binary one, and the absence of a bump represents a binary zero. A laser scans the disc as the disc spins to detect the presence of bumps and gaps, and thus, to generate a binary data stream. The binary data stream is then sent to a system CPU for use by software in the system. The speed at which the system reads a CD-ROM or DVD disc is physically dependent, in part, on how fast the disc spins inside the system.

Hexadecimal data may be stored on a CD-ROM or DVD disc by burning bumps of various sizes onto the surface of the disc, or by segmenting bumps into smaller bumps, such that a variety of bump sizes is present on the disc for representing hexadecimal values. In a preferred embodiment, bumps are segmented into 16 different heights, each representing a half-byte value from 0 to F, as described above. A laser, or an array of lasers, is used to detect the presence of the various bump sizes as the disc spins in the system. By segmenting bumps in this manner, a data capacity increase of eight times or more over current storage discs may be realized.

As an alternative to bump-segmenting, microscopic pictures, symbols, and/or text may be implanted on the disc surface to represent hexadecimal data. A laser, or other suitable nano-image capture device, which is capable of ascertaining which specific images or symbols represent which hexadecimal values, is then used to read the hexadecimal data.

The various methods of transmitting hexadecimal data described herein may be utilized in several different data transmission systems, apart from the analog and fiber optics systems already described. For example, digital subscriber lines (DSL), which operate at high frequencies, could be used to transmit the hexadecimal data. Cable modem systems utilizing coaxial cable, preferably in conjunction with fiber optic cable, may be used to split existing frequencies and transmit them in hexadecimal form. Accordingly, hexadecimal data transmission is particularly beneficial for transmitting large amounts of data along dedicated wires over the “last mile,” from a master destination to individual destinations (such as consumer households), where conserving bandwidth is not important. Wireless networks and devices that transmit radio frequencies at very high speeds may also be used to transmit hexadecimal data. Moreover, any of these various systems and methods may be used in combination with one another to further increase the amount of data that may be transmitted over a given time interval.

Thus while embodiments and applications of the present invention have been shown and described, it would be apparent to one skilled in the art that other modifications and additional variations are possible without departing from the inventive concepts herein. The invention, therefore, is not to be restricted except in the spirit of the claims that follow.

What is claimed is:

1. A method of transmitting data, comprising the steps of:
providing a data stream comprising a plurality of multidecimal characters;
providing a plurality of distinct transmission frequencies;
assigning a unique combination of the distinct transmission frequencies to each distinct multidecimal character in the data stream, each unique combination representing the transmission frequencies at which to send frequency pulses in order to represent the corresponding multidecimal character;
receiving a multidecimal character from the data stream; and
transmitting frequency pulses simultaneously at the unique combination of distinct transmission frequencies assigned to the received multidecimal character; whereby
multidecimal character data is transmitted by frequency pulses.

2. The method of claim 1 wherein the step of providing a plurality of distinct transmission frequencies comprises:
providing four distinct transmission frequencies, and the step of assigning comprises assigning a unique combination of the four transmission frequencies to each of sixteen hexadecimal characters.

3. The method of claim 2 wherein the step of transmitting frequency pulses comprises:
transmitting frequency pulses within a pre-determined time period.

4. The method of claim 1 wherein the step of providing a plurality of distinct transmission frequencies comprises:
providing five distinct transmission frequencies, and the step of assigning comprises assigning a unique combination of the five transmission frequencies to each of sixteen hexadecimal characters.

5. A method for transmitting data, comprising the steps of:
receiving a data stream comprising binary characters;
converting the binary characters into multidecimal character pairs;
splitting each multidecimal character pair into two individual multidecimal characters;
assigning a transmission frequency to each of the individual multidecimal characters; and
sending frequency pulses at the assigned transmission frequencies to a receiver; whereby
binary data is transmitted by frequency pulses representing multidecimal characters.

6. The method of claim 5 wherein the step of converting comprises:
converting the binary characters into hexadecimal character pairs, and the step of assigning comprises assigning 16 distinct analog frequencies to 16 distinct hexadecimal characters.

7. The method of claim 6, further comprising:
assigning a transmission time interval to each of the hexadecimal characters; and
sending frequency pulses alternated with assigned transmission time intervals so that hexadecimal character pairs are transmitted.

8. The method of claim 6 wherein:
the distinct analog frequencies are selected from a frequency range of 400 to 3400 Hz.

9. The method of claim 5 wherein the step of converting comprises:
converting the binary characters into hexadecimal character pairs, and the step of assigning comprises assigning 16 distinct light frequencies to 16 distinct hexadecimal characters for transmission along a fiber optic cable.

10. The method of claim 9 wherein the sending step comprises:
simultaneously sending two light frequencies corresponding to a hexadecimal character pair along a fiber optic cable to create a unique optical signal.

11. A method of transmitting data, comprising the steps of:
receiving a data stream comprising binary characters;
converting the binary characters into multidecimal character pairs;
assigning each of the multidecimal character pairs with a corresponding transmission frequency; and
sending frequency pulses at the assigned transmission frequencies to a receiver; whereby
binary data transmission is converted into and transmitted by frequency pulses representing multidecimal character pairs.

12. The method of claim 11 wherein the step of converting comprises:
converting the binary characters into hexadecimal character pairs, and the step of assigning comprises assigning 256 distinct analog frequencies to 256 distinct hexadecimal character pairs.

13. The method of claim 12, further comprising:
assigning a transmission time interval to each of the hexadecimal character pairs; and
sending frequency pulses alternated with assigned transmission time intervals so that pairs of hexadecimal character pairs are transmitted.

14. The method of claim 12 wherein:
the distinct analog frequencies are selected from a frequency range of 400 to 3400 Hz.

15. The method of claim 11 wherein the step of converting comprises:
converting the binary characters into hexadecimal character pairs, and the step of assigning comprises assigning 256 distinct light frequencies to 256 distinct hexadecimal character pairs for transmission along a fiber optic cable.

16. A method of transmitting a multidecimal data stream, comprising the steps of:
providing a first set of data transmission frequencies and a second set of data transmission frequencies;
segmenting the multidecimal data stream into individual bytes;
segmenting an individual byte into a first half-byte and a second half-byte;
assigning a frequency from the first set of data transmission frequencies to the first half-byte;
determining whether the first half-byte is equal to the second half-byte;
assigning a frequency to the second half-byte by:
assigning a frequency from the first set of data transmission frequencies to the second half-byte if the first half-byte is not equal to the second half-byte, and
assigning a frequency from the second set of data transmission frequencies to the second half-byte if the first half-byte is equal to the second half-byte; and
transmitting simultaneously frequency pulses at the frequency assigned to the first half-byte and the frequency assigned to the second half-byte; whereby
multidecimal data is transmitted by simultaneous frequency pulses.

17. The method of claim 16 wherein:
the first set of data transmission frequencies and the second set of data transmission frequencies each comprise 16 frequencies corresponding to 16 distinct half-bytes.

18. A method of transmitting a multidecimal data stream, comprising the steps of:
providing a first set of data transmission frequencies and a second set of data transmission frequencies;
segmenting the multidecimal data stream into individual bytes;
segmenting an individual byte into a first half-byte and a second half-byte;
assigning a frequency from the first set of data transmission frequencies to the first half-byte;
assigning a frequency from the second set of data transmission frequencies to the second half-byte; and
transmitting simultaneously frequency pulses at the frequency assigned to the first half-byte and the frequency assigned to the second half-byte; whereby
multidecimal data is transmitted by simultaneous frequency pulses.

19. The method of claim 18 wherein:
the first set of data transmission frequencies and the second set of data transmission frequencies each comprise 16 frequencies corresponding to 16 distinct half-bytes.

20. A method of transmitting a multidecimal character value, comprising the steps of:
providing a plurality of binary integer values embodied in a transmission medium, each binary integer value having a distinct transmission frequency at which to transmit frequency pulses associated therewith;
activating a selection of the binary integer values having a sum equal to the multidecimal character value to be transmitted; and
transmitting simultaneously frequency pulses associated with the activated binary integer values such that a unique signal corresponding to the multidecimal character value is transmitted; whereby
the multidecimal character value is transmitted by the unique signal of selected binary integer values.

21. The method of claim 20 wherein the step of providing a plurality of binary integer values comprises:
providing eight binary integer values, each binary integer value having a distinct transmission frequency at which to transmit frequency pulses associated therewith.

22. The method of claim 21 wherein:
the eight binary integer values comprise 1, 2, 4, 8, 16, 32, 64, and 128, respectively, such that multidecimal character values from 0 to 255 may be transmitted.

23. The method of claim 20 further comprising:
the step of selecting the distinct transmission frequencies such that they are spaced apart from one another within a range of available frequencies in order to prevent frequency bleeding.

24. A data transmission system for transmitting and receiving multidecimal data, comprising:
a first multidecimal data encoder for converting a binary data stream into a stream of multidecimal characters;
a frequency assigner assigning the multidecimal characters with distinct transmission frequencies;
a transmission system sending frequency pulses at the distinct transmission frequencies to a receiver; and
a receiving system receiving incoming frequency pulses; whereby
binary data is encoded into multidecimal character frequency pulses for data transmission.

25. The data transmission system of claim 24 wherein:
the encoder is an analog frequency encoder for encoding the multidecimal characters with distinct analog frequencies.

26. The data transmission system of claim 24 further comprising:
a second multidecimal data encoder for converting the incoming frequency pulses received by the receiving system into an incoming multidecimal data stream.

27. The data transmission system of claim 26 further comprising:
a binary data encoder for converting the incoming multidecimal data stream into an incoming binary data stream for processing by a data processing device.

28. The data transmission system of claim 24 further comprising:
a data storage system storing multidecimal character data.

29. The data transmission system of claim 28 wherein the data storage system comprises:
a disc having a plurality of bumps of various sizes disposed on a surface thereof, wherein the disc is selected from the group consisting of: a CD, a CD-ROM, and a DVD.

30. The data transmission system of claim 24 further comprising:
a communication link for providing a communication path between the transmission system and an outside receiver.

31. The data transmission system of claim 30 wherein:
the communication link is selected from the group consisting of: coaxial cable, digital subscriber lines, fiber optic lines, and wireless communication means.

32. A data transmission system for transmitting multidecimal data via a fiber optics network, comprising:
an encoder for converting a binary data stream into a stream of multidecimal characters;
an optical data encoder for encoding the multidecimal characters with distinct optical signals;
a fiber cable having a transmission node including a plurality of fiber strands for transmitting optical signals, each fiber strand representing a distinct integer value used to construct a multidecimal character value;
an optical data transmitter for sending at least one of the distinct optical signals to the transmission node of the fiber cable, the at least one distinct optical signal corresponding to a multidecimal character value to be transmitted; and
an optical signal transmitter for activating a selection of the fiber strands in the transmission node representing integer values having a sum equal to the multidecimal character value to be transmitted; whereby
the binary data stream is transmitted by conversion to multidecimal characters and optical transmission thereof.

33. The data transmission system of claim 32 wherein:
the transmission node includes eight fiber strands representing integer values of 1, 2, 4, 8, 16, 32, 64, and 128, respectively, such that multidecimal character values from 0 to 255 may be transmitted.

34. The data transmission system of claim 32 wherein the fiber cable further comprises:
a receiving node for receiving incoming optical signals, the receiving node including a plurality of fiber strands, each fiber strand representing a distinct integer value used to construct a multidecimal character value.

35. The data transmission system of claim 34 wherein:
the receiving node includes eight fiber strands representing integer values of 1, 2, 4, 8, 16, 32, 64, and 128, respectively, such that multidecimal character values from 0 to 255 may be received.

36. The data transmission system of claim 34 further comprising:
an optical data receiver for receiving optical signals from the receiving node.

37. A data transmission system for transmitting multidecimal data via a fiber optics network, comprising:
an encoder for converting a binary data stream into a stream of multidecimal characters;
an optical data encoder for encoding the multidecimal characters with distinct optical signals;
a plurality of fiber matrices each including a plurality of fiber cables for transmitting and receiving the distinct optical signals;
an optical signal transmitter for sending the distinct optical signals to the plurality of fiber matrices; and
a central fiber core in communication with the plurality of fiber matrices for sending optical signal routing instructions to the fiber matrices; whereby
the binary data stream is transmitted by conversion to multidecimal characters and optical transmission thereof, such optical transmission controllable by the routing instructions.

38. A method of transmitting a multidecimal value, comprising the steps of:
receiving a binary data stream;
converting the binary data stream into a stream of multidecimal characters;
encoding a multidecimal character with optical data corresponding to the multidecimal value to be transmitted;
sending the optical data to a fiber optic cable containing a plurality of fiber strands for transmitting optical data, each fiber strand representing a distinct integer value; and
activating a selection of the fiber strands that represent integer values corresponding to the optical data, such that a distinct optical signal corresponding to the multidecimal value is transmitted along the fiber cable; whereby
the binary data stream is transmitted by optical transmission of the multidecimal character stream.

39. The method of claim 38 wherein the fiber cable comprises:
eight fiber strands representing the integer values of 1, 2, 4, 8, 16, 32, 64, and 128, respectively, such that multidecimal values from 0 to 255 may be transmitted.

40. A method of transmitting characters in a data stream, comprising the steps of:
assigning a unique combination of distinct transmission frequencies to each character in a multidecimal data stream;
transmitting frequency pulses simultaneously over a unique combination of the distinct transmission frequencies that correspond to a character in the multidecimal data stream; and
repeating the step of transmitting frequency pulses simultaneously over a unique combination of the distinct transmission frequencies for each character in the multidecimal data stream; whereby
transmission of multidecimal character data occurs by transmission of frequency pulses.

41. A multidecimal data storage device, comprising:
media providing storage space for multidecimal data; and
said media storing the multidecimal data as multidecimal characters;
whereby
multidecimal data can be stored and read from the multidecimal data storage device.

42. A multidecimal data storage device as set forth in claim 41, further comprising:
the multidecimal data stored as hexadecimal characters.

43. A multidecimal data storage device as set forth in claim 42, further comprising:
the media being selected from the group consisting of CD-ROMs and DVDs; and
the hexadecimal characters stored as one of sixteen different bumps having different heights, the sixteen different bumps corresponding respectively to hexadecimal values 0-F.
